(19) United States
(12) Patent Application Publication
(10) Pub. No.: US 2026/0061886 A1
(43) Pub. Date: Mar. 5, 2026

(54) METHOD FOR MONITORING A STATE OF CHARGE OF A BATTERY

(71) Applicant: Perkins Engines Company Limited, Peterborough (GB)

(72) Inventors: Alexander Charles BROWN, Spalding (GB); Stephen Adam EDWARDS, Peterborough (GB)

(73) Assignee: Perkins Engines Company Limited, Peterborough (GB)

(21) Appl. No.: 19/120,843

(22) PCT Filed: Oct. 6, 2023
(86) PCT No.: PCT/EP2023/025425

§ 371 Date: Apr. 14, 2025

(30) Foreign Application Priority Data
Oct. 14, 2022 (GB) 2215203.7

(51) Int. Cl. B60L 58/13; G01R 31/371; G01R 31/382; H01M 10/42; H02J 7/00

(52) U.S. Cl. CPC B60L 58/13; G01R 31/371; G01R 31/382; H01M 10/425; H02J 7/40; H02J 7/82; H02J 7/933; B60L 2200/40; H01M 2010/4271; H01M 2220/20

(57) ABSTRACT

A method of controlling a state of charge (SOC) of a battery is provided. The method comprises defining a first SOC threshold of the battery, the first SOC threshold being greater than zero and defining a second SOC threshold of the battery, the second SOC threshold being less than a highest charge capacity of the battery. The first and second SOC thresholds define a battery protection charge range of the battery based on a predetermined battery protection charge range associated with the battery. The method also comprises setting a first configurable SOC threshold of the battery, the first configurable SOC threshold being at least the first SOC threshold; and setting a second configurable SOC threshold of the battery, the second configurable SOC threshold being no greater than the second SOC threshold and greater than the first configurable SOC threshold. A range between the first and second configurable SOC thresholds is defined by a configurable capacity associated with the battery. During charging and/or discharging of the battery, the SOC of the battery is controlled based on the first and second configurable SOC thresholds. The configurable capacity of the battery and the first and second configurable SOC thresholds are updatable upon receiving an update to the configurable capacity of the battery.

### FIELD OF THE DISCLOSURE

The present disclosure relates to a battery. In particular, the present disclosure relates to the control of a State of Charge of a battery.

### BACKGROUND

In many applications, it is desirable to know the amount of charge stored in a battery pack. The amount of charge stored in a battery can be expressed as a percentage of the overall charge storage capacity of the battery, i.e. from 0% to 100%. The amount of charge storage as a percentage of the total battery capacity is often referred to as the State of Charge (SOC) of a battery.

It is known that long-term battery health of re-chargeable batteries is affected by the manner in which they are charged and discharged. The speed of charging can affect battery health, as can the state of charge at which they are stored. Regularly discharging a battery to very low, or zero, state of charge may not be beneficial for long-term battery health. Similarly, leaving a battery for a period of time at 100% state of charge may not be beneficial for long-term battery health.

EP-A-4,009,480 discloses a method for managing the charging status or the energy status of an accumulator for optimised ageing.

### SUMMARY

According to a first aspect of the disclosure a method of controlling a state of charge (SOC) of a battery is provided. The method comprises:
defining a first SOC threshold of the battery, the first SOC threshold being greater than zero;
defining a second SOC threshold of the battery, the second SOC threshold being less than a highest charge capacity of the battery,
wherein the first and second SOC thresholds define a battery protection charge range of the battery based on a predetermined battery protection charge range associated with the battery;
setting a first configurable SOC threshold of the battery, the first configurable SOC threshold being at least the first SOC threshold;
setting a second configurable SOC threshold of the battery, the second configurable SOC threshold being no greater than the second SOC threshold and greater than the first configurable SOC threshold, wherein a range between the first and second configurable SOC thresholds is defined by a configurable capacity associated with the battery; and
during charging and/or discharging of the battery, the SOC of the battery is controlled based on the first and second configurable SOC thresholds, wherein
the configurable capacity of the battery and the first and second configurable SOC thresholds are updatable upon receiving an update to the configurable capacity of the battery.

According to the method of the first aspect, the State of Charge of the battery is controlled between two pairs of SOC thresholds. The first and second SOC thresholds define a predetermined battery protection charge range associated with the battery. According to the method of the first aspect, the SOC of the battery is controlled such that the SOC does not fall below these thresholds. Accordingly, the first SOC threshold prevents the battery from being discharged to a zero, or very low SOC. The second SOC threshold prevents the battery from being charged to a very high, or fully charged (e.g. 100% SOC) capacity. The thresholds prevent the battery from being discharged or charged in a manner which damages the long-term health of the battery.

In addition to the predetermined battery protection charge range, the method of the first aspect also provides the battery with a configurable capacity based on the first and second configurable SOC thresholds. Thus, the battery available for use can be configured (and reconfigured) via the method of the first aspect. That is to say, the configurable capacity of the battery defined by the first and second SOC thresholds can be updated without having to physically change the battery.

In some embodiments, the method further comprises mapping a SOC of the battery to a user display SOC range. In some embodiments, the first configurable SOC threshold is mapped to a value indicative of 0% SOC of the user display SOC range. In some embodiments, the second configurable SOC threshold is mapped to value indicative of 100% SOC of the user display SOC range. In some embodiments, the method further comprises outputting the mapped SOC of the battery to a user display. Accordingly, the method of the first aspect may map the configurable capacity of the battery to a user display SOC range. As such, the amount of battery charge available to a user (based on the configurable capacity) may be displayed to a user in a straightforward manner. Furthermore, any updates to the configurable capacity will result in the new first and second configurable SOC thresholds being mapped to the user display SOC range. Thus, the user display may also be updated without requiring any hardware changes.

In some embodiments, the position of configurable capacity defined by the first and second configurable SOC thresholds withing the battery protection range is configurable based on a trim parameter associated with the battery. The trim parameter may allow the configurable capacity to be optimised within the battery protection range. In particular, by locating the configurable capacity closer towards the first SOC threshold than the second SOC threshold, the battery may not be charged to as high SOC levels. This in turn may improve the lifetime of the battery. By locating the configurable capacity closer to the second SOC threshold, the voltage (and therefore power output) available to a user may be improved. As such, a user may optimise the configurable capacity to favour battery lifetime, power output, or a balanced approach.

In some embodiments, the position of configurable capacity defined by the first and second configurable SOC thresholds is updatable upon receiving an update to the trim parameter. As such, the configurable capacity of the battery may be updated to favour battery lifetime or power output without requiring any changes to the hardware of the battery.

In some embodiments, the first SOC threshold is at least 5% of the highest charge capacity of the battery. As such, the first SOC threshold may prevent the battery from being discharged below a SOC of about 5%, in order to prevent the battery from being discharged in a manner which may damage the battery lifetime. In some embodiments, the second SOC threshold is no greater than 95% of the highest charge capacity of the battery. As such, the second SOC threshold may prevent the battery from being charge above a SOC of about 95%, in order to prevent the battery from being overcharged in a manner which may damage the battery lifetime.

In some embodiments, the method is performed by a battery management system connected to the battery control the SOC of the battery. As such, the SOC of the battery may be controlled by a battery management system connected to the battery in accordance with the method of the first aspect.

In some embodiments, the battery management system receives an update communication, wherein the update communication causes the configurable capacity of the battery to be updated. That is to say, the configurable capacity of the battery (and thus the first and second configurable SOC thresholds) may be updated based on a change in the configurable capacity according to the received communication. The communication may be received by the battery management system via any suitable data transmission method. For example, in some embodiments, the communication may be received over a wired connection, such a communication with a diagnostic tool or other hardware. In some embodiments, the battery management system receives the update communication over a wireless network, such as a wireless internet network, radio telecommunications network, or wireless personal area network.

In some embodiments, the battery is provided as part of an electric work vehicle. By electric work vehicle, it is understood that the electric work vehicle does not include an internal combustion engine. As such, the battery of the electric work vehicle (which may not be readily accessible depending on the configuration of the work) can be configured (and reconfigured) based on updates to the configurable capacity without requiring access to the battery.

In some embodiments, during discharging of the battery, a maximum discharge current of the battery is modified based on the SOC of the battery and the first configurable SOC threshold. In some embodiments, when the SOC of the battery is within range defined by the first and second configurable SOC thresholds, the maximum discharge current is unchanged. For example, the battery may have a maximum discharge current level which the battery can output at a steady state without overheating. Such a maximum discharge current may be a predetermined value, or calculated from a look-up table based on known relationships between SOC, temperature, and the maximum discharge current for the battery. When the SOC of the battery is above the first configurable SOC threshold, the method may allow the battery to output 100% of the maximum discharge current the battery can safely output (i.e. the maximum discharge current is unchanged by the method).

In some embodiments, when the SOC of the battery is below the first configurable SOC threshold the maximum discharge current is reduced to zero. Thus, the method according to the first aspect may control the SOC of the battery within the range defined by the configurable capacity. As the configurable capacity cannot extend outside of the battery protection range, the method according to the first aspect improves battery lifetime by reducing or preventing excessive discharging of the battery.

In some embodiments, when the SOC of the battery is decreased below the first configurable SOC threshold by no more than a first SOC overshoot range, the maximum discharge current is reduced from the maximum discharge current towards zero over the first SOC overshoot range of the battery. It will be appreciated that in accordance with the method of the first aspect, the configurable capacity of the battery available to a user of the battery is smaller than the total battery capacity. In some embodiments, the method of the first aspect may provide a first SOC overshoot range to enable the battery to be discharged in a limited manner when the SOC of the battery drops below the first configurable SOC threshold. In effect, the battery may provide some “reserve power” once the configurable capacity has been exhausted to allow for, for example, emergency operation of the battery. Over the first SOC overshoot range, the maximum discharge output by the battery may be reduced from the predetermined value (e.g. 100% of maximum discharge current) towards 0% of maximum discharge current over the first SOC overshoot range. Thus, it will be appreciated that the current available for use reduces as the battery is further discharged in the first SOC overshoot range. Accordingly, by reducing the maximum discharge current available, the power output of the battery further reduces as the battery is further discharged over the first SOC overshoot range.

In some embodiments, during charging of the battery, a maximum charge current of the battery is modified based on the SOC of the battery and the second configurable SOC threshold. In some embodiments, when the SOC of the battery is within range defined by the first and second configurable SOC thresholds, the maximum charge current is unchanged. Such a maximum charge current may be a predetermined value, or calculated from a look-up table based on known relationships between SOC, temperature, and the maximum charge current for the battery. When the SOC of the battery below the second configurable SOC threshold, the method may allow the battery to receive 100% of the maximum charge current the battery can safely receive (i.e. the maximum charge current is unchanged by the method).

In some embodiments, the maximum charge current may be the same magnitude as the maximum discharge current. In other embodiments, the maximum charge current and maximum discharge currents may be different. It will be appreciated that the principle of controlling the maximum charge current and maximum discharge current may be applied to control of maximum steady state currents of the battery and also to maximum pulse currents of the battery.

In some embodiments, when the SOC of the battery is above the second configurable SOC threshold the maximum charge current is reduced to zero.

In some embodiments, when the SOC of the battery is increased above the second configurable SOC threshold by no more than a second SOC overshoot range, the maximum charge current is reduced from the maximum charge current towards zero over the second SOC overshoot range of the battery. Thus, in some embodiments the method of the first aspect may provide a second SOC overshoot range to enable the battery to be charged in a limited manner when the SOC exceeds the second configurable SOC threshold.

According to a second aspect of the disclosure, a controller for monitoring a state of charge (SOC) of a battery. The controller is configured to:
define a first SOC threshold of the battery, the first SOC threshold being greater than zero;
define a second SOC threshold of the battery, the second SOC threshold being less than a highest charge capacity of the battery,
wherein the first and second SOC thresholds define a battery protection charge range of the battery based on a predetermined battery protection charge range associated with the battery;
set a first configurable SOC threshold of the battery, the first configurable SOC threshold being at least the first SOC threshold;
set a second configurable SOC threshold of the battery, the second configurable SOC threshold being no greater than the second SOC threshold and greater than the first configurable SOC threshold, wherein a range between the first and second configurable SOC thresholds is defined by a configurable capacity associated with the battery;
control the SOC of the battery during charging and/or discharging of the battery based on the first and second configurable SOC thresholds; and
to update the configurable capacity of the battery and the first and second configurable SOC thresholds upon receiving an update to the configurable capacity of associated with the battery.

It will be appreciated that the controller may be configured to perform the method of the first aspect of the disclosure. Thus, the controller may also be configured to perform any of the optional method features discussed above.

According to a third aspect of the disclosure, a computer program product is provided comprising instructions to cause the controller of the second aspect to execute the method of the first aspect.

According to a fourth aspect of the disclosure, a computer-readable storage medium having stored thereon the computer program of the third aspect is provided.

### BRIEF DESCRIPTION OF THE FIGURES

A specific embodiment of the disclosure will now be described, by way of example only, with reference to the accompanying figures in which:

FIG. 1 shows a schematic diagram of an electric work vehicle;

FIG. 2 shows a schematic diagram of the different SOC ranges according to this disclosure;

FIG. 3 shows a graph of a mapping of the Actual SOC to a Mapped SOC according to this disclosure; and

FIG. 4 shows a graph of a maximum discharge current and a maximum charge current.

### DESCRIPTION

With reference to FIG. 1, an electric work vehicle 100 is provided. The electric work vehicle comprises a (rechargeable) battery (not shown). The battery may be connected to a charging module (not shown) for charging. The electric work vehicle may also comprise a controller for controlling the state of charge of the battery (e.g. a battery management system). The specific electric work vehicle 100 in FIG. 1 is shown as an example. The electric work vehicle 100 may comprise any other type of electric work vehicle. Of course, it will be appreciated that the present disclosure is not limited to batteries for electric work vehicles. For example, batteries according to this disclosure may be any battery suitable for use in an electric vehicle, or other as part of a (rechargeable) power pack for a worksite.

According to this disclosure, the battery has a State of Charge (SOC which ranges from 0% SOC (i.e. fully discharged) to 100% SOC (i.e. fully charged). According to this disclosure, the SOC of the battery can range from 0% SOC to 100% SOC. It will be appreciated that the SOC of the battery cannot drop below 0% SOC and cannot exceed 100% SOC.

The electric work vehicle may also comprise a controller (battery management system) which is configured to control the charging and/or discharging of the battery. The controller (not shown in FIG. 1) may be configured to perform a method of controlling a SOC of a battery according to this disclosure as discussed in more detail below.

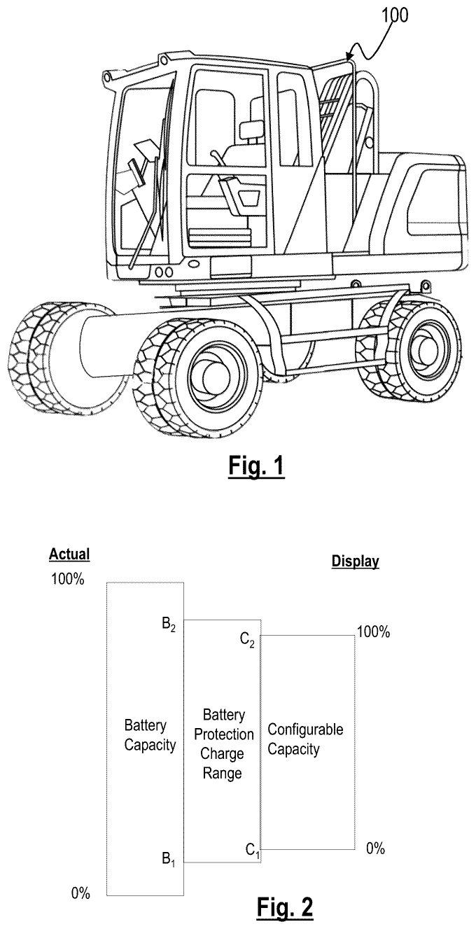

According to an embodiment of the disclosure, a method of controlling the SOC of the battery of the electric work vehicle of FIG. 1 is provided. The method comprises defining a first SOC threshold (B₁) of the battery, the first SOC threshold (B₁) being greater than zero (i.e. greater than 0% SOC of the battery). The method also comprises defining a second SOC threshold (B₂) of the battery, the second SOC threshold (B₂) being less than a highest charge capacity of the battery (i.e. less than 100% SOC). The first and second SOC thresholds (B₁, B₂) define a battery protection charge range of the battery based on a predetermined battery protection charge range associated with the battery. The first and second SOC thresholds (B₁, B₂) and the battery protection charge range are indicated on the schematic diagram of FIG. 2, which shows the battery protection charge range relative to the SOC range of the battery (from 0% SOC to 100% SOC).

As the first and second SOC thresholds B₁, B₂ are intended to represent SOC thresholds of the battery, the first and second SOC thresholds B₁, B₂ may each be represented by a value between 0 and 1.

The predetermined battery protection charge range and the first and second SOC thresholds (B₁, B₂) may be stored by the controller or in a memory associated with the controller. The predetermined battery protection charge range and the first and second SOC thresholds (B₁, B₂) may be set based on the characteristics of the battery and the desired operating characteristics of the battery. In general, increasing the predetermined battery protection charge range increases the available capacity of the battery. Decreasing the predetermined battery protection charge range may reduce the extent to which the battery is charged to a high level of charge (i.e. towards 100% SOC) or discharged to a low level of charge (i.e. towards 0% SOC), which in turn improves battery lifetime.

For example, in some embodiments the first SOC threshold B₁ may be at least 5% of the highest charge capacity of the battery. That is to say, the first SOC threshold B₁ may be set at an SOC of the battery of at least 5% SOC. In some embodiments, the first SOC threshold may be at least: 7% SOC, 10% SOC or 15% SOC.

For example, in some embodiments, the second SOC threshold B₂ may be no greater than 95% of the highest charge capacity of the battery. That is to say, the second SOC threshold B₂ may be set at an SOC of the battery of no greater than 95% SOC. In some embodiments, the second SOC threshold may be no greater than 92% SOC, 90% SOC, or 85% SOC.

As such, the battery protection charge range may define a range of SOC available for use. For example in the diagram of FIG. 2, the battery protection charge range corresponds to an SOC range of 100%-B₁-B₂, where B₁ and B₂ are expressed in terms of % SOC. For example in some embodiment the battery protection charge range may be about: 80, 85, or 90% of the capacity of the battery.

According to the embodiment, the method also comprises setting a first configurable SOC threshold of the battery (C₁). The first configurable SOC threshold C₁ is at least the first SOC threshold B₁. The method also comprises setting a second configurable SOC threshold of the battery C₂. The second configurable SOC C₂ threshold is no greater than the second SOC threshold B₂ and greater than the first configurable SOC threshold C₁. A range between the first and second configurable SOC thresholds C₁, C₂ is defined by a configurable capacity associated with the battery. The first and second configurable SOC thresholds C₁, C₂ and the configurable capacity are shown in the diagram of FIG. 2. As such, the configurable capacity of the battery is a no greater than the capacity defined by the battery protection charge range. By restricting the configurable capacity in this manner, the battery may be controlled in such a manner so as to improve its lifetime.

As the first and second configurable SOC thresholds C₁, C₂ are intended to represent SOC thresholds of the battery, the first and second configurable SOC thresholds C₁, C₂ may each be represented by a value between 0 and 1. The configurable capacity may also be expressed in terms of a percentage of the battery capacity (i.e. a value between 0 and 1)

In some embodiments, a trim parameter may be used to specify the position of the configurable capacity within the battery protection range. As such, the trim parameter (T) may define the positions of the first and second configurable SOC thresholds C₁, C₂ relative to the positions of the first and second SOC thresholds B₁, B₂. The trim parameter (T) may be at least 0 and no greater than 1. The trim parameter may be used to determine the first and second configurable SOC thresholds C₁, C₂ based on a configurable capacity (U). For example, the following equations may be used to calculate C₁, C₂:

$${C}_{1} = max ( {B}_{1} , {B}_{1} + ( ( {B}_{2} - {B}_{1} - U ) \times T ) ) ; and$$

$${C}_{2} = min ( {B}_{2} , {C}_{1} + U )$$

That is to say, the first configurable SOC threshold is the maximum of the first SOC threshold B₁ and the SOC value defined by B₁+ ((B₂-B₁-U)×T). As such, the first configurable SOC threshold is at least equal to B₁. The second configurable SOC threshold is the minimum of the second SOC threshold and the value defined by C₁+U. As such, the second configurable SOC threshold is no greater than B₂.

Thus, it will be appreciated that the trim parameter T may be used to shift the relative position of the configurable capacity U within the battery protection charge range. For example, when T=1, the second configurable SOC threshold C₂ will be positioned such that it is equal to the second SOC threshold B₂. When T=0, the first configurable SOC threshold C₁ will be positioned such that it is equal to the first SOC threshold B₁.

In some embodiments where no trim parameter is provided, or not updated, the trim parameter may take a default value. For example, a default value may be T=0.5 in order to balance the configurable capacity at a centre of the battery protection charge range.

In some embodiments, the position of the configurable capacity U defined by the first and second configurable SOC thresholds C₁, C₂ within the battery protection range is updatable upon receiving an update to the trim parameter T. For example, the trim parameter may be increased to shift the configurable capacity U towards a higher SOC level in order to improve power output. Alternatively, the trim parameter may be decreased to shift the configurable capacity towards a lower SOC level in order to improve battery lifetime.

The method also comprises controlling the SOC of the battery during charging and discharging of the battery based on the first and second configurable SOC thresholds. That is to say, during use of the battery (either charging or discharging), the SOC stays within the range defined by the first and second configurable SOC thresholds.

In some embodiments, the method also comprises outputting a State of Charge of the battery to a user display. For example, in the embodiment of FIG. 1, the user display may be provided in a cabin of the electric work vehicle. The user display may be configured to indicate a SOC of the battery to a user. In some embodiments, the user display may comprise a numerical indication of SOC (e.g. 0% to 100% SOC), or the user display may comprise a graphical representation of SOC of the battery (e.g. a series of bars indicating SOC). In either case, the user display may indicate the SOC of the battery based on a SOC value between 0 and 1 provided by the controller (corresponding to a SOC range of 0% to 100% SOC).

In some embodiments, the SOC indicated on the user display may correspond to the charge remaining within the configurable capacity, rather than the SOC of the battery. In such a case, the controller may output a mapped SOC value to the user display, rather than a value representative of the SOC of the battery.

In order to output a mapped SOC value, the controller may map the first configurable SOC threshold C₁ to a value indicative of 0% SOC of the user display SOC range and the second configurable SOC threshold C₂ is mapped to a value indicative of 100% SOC of the user display SOC range.

For example, where the user display requires a SOC value between 0 and 1, the controller may map a SOC of the battery(S) to a mapped SOC (M) using the following equation:

$$M = ( S - {C}_{1} ) / U$$

An example of such a mapping is shown in the graph of FIG. 3.

In some embodiments, it may be possible for the SOC of the battery to fall outside of the SOC range defined by the configurable capacity (see below). In such cases, the user display may not be provided with such a value. For example, the mapped SOC may also have a condition that where M>1, the mapped SOC output is 1 (i.e. 100% SOC). Similarly, where M<0, the mapped SOC output may be 0.

The method also allows the configurable capacity of the battery to be updated. As such, the configurable capacity of the battery and the first and second configurable SOC thresholds are updatable upon receiving an update to the configurable capacity of the battery. As such, in some embodiments the method may also comprise the controller (battery management system) receiving an update communication. Upon receipt of the communication, the configurable capacity (U) of the battery is then updated. In some embodiments, the communication may be received over a wireless network. That is to say, the controller may be connected to a receiver which receives communications from the wireless network. In other embodiments, the controller may be connected to a diagnostic tool or other computer terminal via a wired connection (e.g. a Universal Serial Bus connection) in order to receive the communication.

In some embodiments, controlling the SOC of the battery according to the method of the disclosure may include that during discharging of the battery a maximum discharge current of the battery is controlled based on the SOC of the battery and the first configurable SOC thresholds. For example, a look-up table may be provided which indicates a maximum discharge current for the battery. Discharge currents exceeding this magnitude may cause excessive heating of the battery, which is to be avoided. In some embodiments, the maximum discharge current stored in the look-up table may require inputs of current SOC of the battery and temperature. According to the method of the embodiment, the controller may modify the indicated maximum discharge current based on the first configurable SOC thresholds (C₁) and the current SOC of the battery.

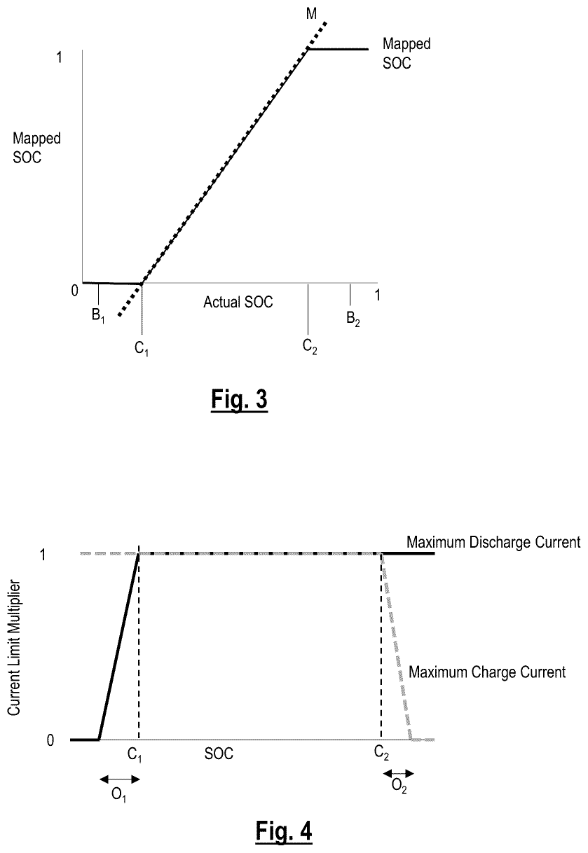

FIG. 4 shows a graph of a method of controlling the maximum discharge current of the battery according to this disclosure. As shown in FIG. 4, a current multiplier is applied to the maximum discharge current. When the SOC of the battery is equal or above first configurable SOC threshold (C₁) the multiplier is 100%. That is to say, the maximum discharge current magnitude is unchanged from the value indicated in the lookup table. Below the first configurable SOC threshold (C₁), the multiplier is modified in order to control the modify the maximum discharge current capable of being output by the battery. For example, when the SOC of the battery is below the first configurable SOC threshold, the maximum discharge current may be reduced to zero.

In some embodiments, the multiplier may be zero for any SOC of the battery less than the first configurable SOC threshold C₁.

In the embodiment of FIG. 4, the method provides for a small amount of overshoot of the configurable capacity. That is to say, the method may allow the SOC of the battery to be discharge below the first configurable SOC threshold by a predetermined amount to assist with the operation of the electric work vehicle. For example, as shown in FIG. 4, a first SOC overshoot range O₁ is provided. Thus, when the SOC of the battery is reduced below the first configurable SOC threshold C₁ by no more than the first SOC overshoot range O₁, the maximum discharge current is modified from 100% of maximum discharge current to zero (i.e. 0% of the maximum discharge current) over the first SOC overshoot range. That is to say, the multiplier applied to the maximum discharge current decreases from 1 to 0 over the first overshoot range O₁. In the embodiment of FIG. 4, the multiplier is reduced linearly over the first overshoot range O₁. In other embodiments, parabolic or other non-linear relationships may be provided to reduce the multiplier from 1 to 0 over the first overshoot range O₁. By reducing the maximum discharge current over this range, the functionality of the electric work vehicle may be limited once the configurable capacity has been exhausted. However, the first overshoot range may provide for some “reserve power” to allow the electric work vehicle to reach a charging point for example. The size of the first overshoot range may be updatable, similar to other parameters discussed above.

In the embodiment of FIG. 4, the size of the first overshoot range O₁ is about 5% of the battery capacity. In other embodiments, the first overshoot range O₁ may be at least 3%, 5%, or 7% of the batter capacity. In some embodiments, where the first overshoot range is provided, the trim parameter T and/or the configurable capacity U may be adjusted to ensure that first overshoot range does not overlap the first SOC threshold B₁.

FIG. 4 also shows a graph of a method of controlling the maximum charge current of the battery according to this disclosure. As shown in FIG. 4, a current multiplier is applied to the maximum charge current. When the SOC of the battery is equal or below the second configurable SOC threshold (C₂) the multiplier is 100%. That is to say, the maximum charge current magnitude is unchanged from the value indicated in the lookup table. Above the second configurable SOC threshold (C₂), the multiplier is modified in order to control the modify the maximum charge current capable of being received by the battery. For example, when the SOC of the battery is above the second configurable SOC threshold, the maximum charge current may be reduced to zero.

In some embodiments, the multiplier may be zero for any SOC of the battery greater than the second configurable SOC threshold C₂.

In some embodiments, for example as shown in FIG. 4, a second SOC overshoot range O₂ is provided. Thus, when the SOC of the battery is increased above the second configurable SOC threshold C₂ by no more than the second SOC overshoot range O₂, the maximum charge current is reduced from the maximum charge current towards zero over the second SOC overshoot range. That is to say, the multiplier applied to the maximum charge current decreases from 1 to 0 over the second overshoot range O₂. In the embodiment of FIG. 4, the multiplier is reduced linearly over the second overshoot range O₂. In other embodiments, parabolic or other non-linear relationships may be provided to reduce the multiplier from 1 to 0 over the second overshoot range O₂. By reducing the maximum charge current available over this range, the charging of the battery may be slowly ramped down once the battery is charged over the configurable capacity. The additional power may provide the electric work vehicle with some additional “reserve power”, which may be made available to a user or to perform tasks while the electric work vehicle is idle. The size of the second overshoot range may be updatable, similar to other parameters discussed above.

In the embodiment of FIG. 4, the size of the second overshoot range O₂ is about 5% of the battery capacity. In other embodiments, the second overshoot range O₂ may be at least 3%, 5%, or 7% of the batter capacity. In some embodiments, where the second overshoot range is provided, the trim parameter T and/or the configurable capacity U may be adjusted to ensure that second overshoot range does not overlap the second SOC threshold B₂.

### INDUSTRIAL APPLICABILITY

According to this disclosure, a method and controller for controlling a SOC of a battery is provided. According to this disclosure, the SOC of the battery is controlled between two pairs of SOC thresholds. The first and second SOC thresholds define a predetermined battery protection charge range associated with the battery. According to the method of the first aspect, the SOC of the battery is controlled such that the SOC does not fall below these thresholds. Accordingly, the first SOC threshold prevents the battery from being discharged to a zero, or very low SOC. The second SOC threshold prevents the battery from being charged to a very high, or fully charged (e.g. 100% SOC) capacity. The thresholds prevent the battery from being discharged or charged in a manner which damages the long-term health of the battery.

In addition to the predetermined battery protection charge range, the method of the first aspect also provides the battery with a configurable capacity based on the first and second configurable SOC thresholds. Thus, the battery available for use can be configured (and reconfigured) via the method of the first aspect. That is to say, the configurable capacity of the battery defined by the first and second SOC thresholds can be updated without having to physically change the battery.

In some embodiments, the battery is provided as part of an electric work vehicle. By electric work vehicle, it is understood that the electric work vehicle does not include an internal combustion engine. As such, the battery of the electric work vehicle (which may not be readily accessible depending on the configuration of the work) can be configured (and reconfigured) based on updates to the configurable capacity without requiring access to the battery.

1. A method of controlling a state of charge (SOC) of a battery, the method comprising:
defining a first SOC threshold of the battery, the first SOC threshold being greater than zero;
defining a second SOC threshold of the battery, the second SOC threshold being less than a highest charge capacity of the battery,
wherein the first and second SOC thresholds define a battery protection charge range of the battery based on a predetermined battery protection charge range associated with the battery;
setting a first configurable SOC threshold of the battery, the first configurable SOC threshold being at least the first SOC threshold;
setting a second configurable SOC threshold of the battery, the second configurable SOC threshold being no greater than the second SOC threshold and greater than the first configurable SOC threshold, wherein a range between the first and second configurable SOC thresholds is defined by a configurable capacity associated with the battery; and
during charging and/or discharging of the battery, the SOC of the battery is controlled based on the first and second configurable SOC thresholds, wherein
the configurable capacity of the battery and the first and second configurable SOC thresholds are updatable upon receiving an update to the configurable capacity of the battery.

2. The method according to claim 1, further comprising:
mapping a SOC of the battery to a user display SOC range, wherein the first configurable SOC threshold is mapped to a value indicative of 0% SOC of the user display SOC range and the second configurable SOC threshold is mapped to value indicative of 100% SOC of the user display SOC range;
outputting the mapped SOC of the battery to a user display.

3. The method according to claim 1, wherein
the position of configurable capacity defined by the first and second configurable SOC thresholds within the battery protection range is configurable based on a trim parameter associated with the battery.

4. The method according to claim 3, wherein
the position of configurable capacity defined by the first and second configurable SOC thresholds is updatable upon receiving an update to the trim parameter.

5. The method according to claim 1, wherein
the first SOC threshold is at least 5% of the highest charge capacity of the battery; and/or
the second SOC threshold is no greater than 95% of the highest charge capacity of the battery.

6. The method according to claim 1, wherein
a battery management system connected to the battery control the SOC of the battery.

7. The method according to claim 6, wherein
the battery management system receives an update communication,
wherein the update communication causes the configurable capacity of the battery to be updated.

8. The method according to claim 6, wherein
the battery management system receives the update communication over a wireless network.

9. The method according to claim 1, wherein
the battery is provided as part of an electric work vehicle.

10. The method according to any of claim 1, wherein
during discharging of the battery, a maximum discharge current of the battery is modified based on the SOC of the battery and the first configurable SOC threshold.

11. The method according to claim 10, wherein
when the SOC of the battery is above or equal to the first configurable SOC threshold, the maximum discharge current is unchanged.

12. The method according to claim 10, wherein
when the SOC of the battery is below the first configurable SOC threshold the maximum discharge current is reduced to zero.

13. The method according to claim 10, wherein
when the SOC of the battery is decreased below the first configurable SOC threshold by no more than a first SOC overshoot range, the maximum discharge current is reduced from the maximum discharge current towards zero over the first SOC overshoot range of the battery.

14. The method according to claim 1, wherein
during charging of the battery, a maximum charge current of the battery is modified based on the SOC of the battery and the second configurable SOC threshold.

15. The method according to claim 14, wherein
when the SOC of the battery below or equal to the second configurable SOC threshold, the maximum charge current is unchanged.

16. The method according to claim 14, wherein
when the SOC of the battery is above the second configurable SOC threshold the maximum charge current is reduced to zero.

17. The method according to claim 14, wherein
when the SOC of the battery is increased above the second configurable SOC threshold by no more than a second SOC overshoot range, the maximum charge current is reduced from the maximum charge current towards zero over the second SOC overshoot range of the battery.

18. A controller for monitoring a state of charge (SOC) of a battery of an electric work vehicle, the controller configured to:
define a first SOC threshold of the battery, the first SOC threshold being greater than zero;
define a second SOC threshold of the battery, the second SOC threshold being less than a highest charge capacity of the battery,
wherein the first and second SOC thresholds define a battery protection charge range of the battery based on a predetermined battery protection charge range associated with the battery;
set a first configurable SOC threshold of the battery, the first configurable SOC threshold being at least the first SOC threshold;
set a second configurable SOC threshold of the battery, the second configurable SOC threshold being no greater than the second SOC threshold and greater than the first configurable SOC threshold, wherein a range between the first and second configurable SOC thresholds is defined by a configurable capacity associated with the battery;
control the SOC of the battery during charging and/or discharging of the battery based on the first and second configurable SOC thresholds; and
to update the configurable capacity of the battery and the first and second configurable SOC thresholds upon receiving an update to the configurable capacity of associated with the battery.
